(19) United States
(12) Patent Application Publication
(10) Pub. No.: US 2012/0118380 A1
(43) Pub. Date: May 17, 2012

(54) Solar Reflective Fibre

(76) Inventor: Peter Leaback, London (GB)

(21) Appl. No.: 13/387,274

(22) PCT Filed: Jul. 30, 2010
(86) PCT No.: PCT/GB2010/051258

§ 371 Date: Jan. 26, 2012

(30) Foreign Application Priority Data
Jul. 31, 2009 (GB) 0913376.0

(51) Int. Cl. H01L 31/0232; A62B 17/00; G02B 1/10

(52) U.S. Cl. 136/259; 359/584; 2/458

(57) ABSTRACT

A solar reflective fibre having a longitudinal axis, the fibre comprising: a substantially continuous primary portion having a first refractive index; and a plurality of secondary portions, each secondary portion having a second refractive index different from the first refractive index. The primary and secondary portions are arranged to run substantially continuously along at least a portion of a length of the fibre, the primary portion providing a host medium within which the secondary portions are provided. The primary and secondary portions are arranged to constitute a dielectric mirror structure whereby a phase of a plurality of scattered beams of radiation each beam being scattered at one of a plurality of respective interfaces between primary and secondary portions interfere constructively with one another thereby to reduce an amount of radiation transmitted through the fibre.

### FIELD OF THE INVENTION

The present invention relates to solar reflectors. In particular the invention relates to fibres arranged to reflect solar radiation.

### BACKGROUND

It is well known that white clothing can be effective in keeping a wearer of the clothing cooler when exposed to sunlight compared with coloured clothing including black clothing. This is because less light is absorbed by white cloth compared to coloured cloth.

Light absorbed by clothing is typically transformed into heat which in turn heats the body. The body compensates for the heating effect of the cloth heating by sweating which causes dehydration and discomfort.

White clothing is however a relatively poor reflector. A white T-shirt will typically transmit 60% of the light falling upon it. A human body covered in white clothing and exposed to bright sunlight, can have a net absorption of 160 Watts per square meter. By comparison, the difference in energy used by the body when sedentary (e.g. sitting down) and that when performing light exercise (e.g. a light jog) is around 100 watts per square meter.

Thus, the heating effect of sitting in direct sunlight can feel similar to that of light exercise in the shade (on a hot day).

If a polymer fibre could be created that reflected 90% of solar radiation, a body covered in this fabric would have a net absorption of roughly 15 watts per square meter. This absorption rate would be similar to that of a body in shade. Apparel exhibiting this performance would be of particular benefit to endurance athletes.

In hot weather a marathon runner can lose water through sweating at a greater rate than the body can absorb water in the stomach. This unsustainable situation causes reduced performance in the latter stages of a race.

Apparel that reduced the heat load on the athlete by 145 watts per square meter could make the difference between a body remaining fully hydrated and a body experiencing progressive dehydration.

Current reflective clothing technology has concentrated on metallized cloth, which is designed to reflect intense heat encountered by fire fighters. Metallized cloth is not ideal for keeping an object cool when exposed to solar radiation due to the reflective properties of metals over a wide range of wavelengths. Thus although heat incident upon the cloth from the sun is generally reflected away from the object, heat radiating from the object is reflected back towards the object by the cloth (the cloth acting as thermal insulation).

Solar radiation that reaches the ground has wavelengths roughly in the range from around 300 to around 2500 nm. The human body radiates at roughly 10,000 nm. An ideal material for keeping the body cool in sunlight would therefore be highly reflective in the range 300 to 2500 nm but not at around 10,000 nm.

It is to be understood that if the material were highly reflective at a wavelength of 10,000 nm body heat would be reflected back towards the body, thus providing thermal insulation.

Aluminised cloth has a high reflectivity (65%) at solar wavelengths and at the wavelengths of heat emitted by the human body. Thus it is not ideal for use in clothing intended to assist a wearer in remaining cool. Aluminised plastic sheeting for example is widely used as a thermal blanket for treating people with hypothermia.

A type of reflector that can be designed to have high reflectivity of solar radiation but low reflectivity of body radiation may be made from a non-metallic (dielectric) material in the form of a dielectric mirror.

An example of a dielectric reflecting material is a solar reflecting paint. Solar reflecting paint consists of microscopic particles of pigment (usually titanium dioxide) suspended in a clear varnish or other medium. As light enters the paint, it is refracted as it transitions between the titanium dioxide and the varnish. Random scattering occurs which results in some of the light being reflected out of the paint and some of the light becoming absorbed by the paint.

A good solar reflective paint will reflect about 50% of solar radiation incident upon it.

The size of the titanium dioxide particles is chosen to create a high degree of scattering at solar radiation wavelengths (described above), but only a small amount of scattering at wavelengths that a hot building will emit. This is a great advantage of titanium dioxide paint over metal paint; a building will readily re-radiate the energy it has absorbed from the sun when covered in titanium dioxide paint compared with metallic paint.

Solar reflective paint that is used on flat roofs has been proven to significantly reduce an amount of energy required to run air conditioning systems and increase the lifespan of the roof.

If a UV resistant polymer fibre could be created with a reflectivity of over 90% to solar radiation, the air conditioning costs of buildings could be reduced still further by incorporating such a fibre on the roof.

Another application of a highly reflective polymer fibre would be as a low cost solar concentrator. A solar concentrator directs light to a small area which contains a device that exploits the solar energy.

Possible advantages of a solar concentrator made from a reflective polymer fibre are the reduced weight of such a concentrator compared with glass/metal reflectors, and the possibility of deforming the reflective surface in real time to best direct sunlight as the sun moves during the day.

A further application of a highly reflective polymer fibre would be in the construction of ultra-lightweight clothing. There are limiting factors in respect of how thin a fabric can be manufactured and still be useful for garments. These factors include the tensile strength of thread from which the fabric is woven and the light scattering properties of the fabric.

In thinner fabrics photons have fewer transitions between air and the fibres as the photons pass through the fabric compared with thicker fabrics. This reduces the amount of light that is scattered/reflected and consequently fabrics becomes increasingly translucent as they become thinner.

The majority of garments are designed to be completely opaque, which limits how thin they can be made. It is to be understood that a more highly reflective fibre could be woven to form a much thinner fabric whilst retaining an opacity in excess of that obtainable using known fibres.

U.S. Pat. No. 7,311,962 describes a reflective fibre created by producing concentric rings of two materials with differing refractive indices. A disadvantage of this technique is that the cost of the two materials is higher than that of polymers normally used in the fabric industry.

US 2008/0152282 describes a scheme for creating photonic crystal fibres which guide light along the length of the fibres.

US 2003/0174986 describes a photonic crystal formed from a hollow core optical fibre that is itself formed from a collection of smaller hollow core optical fibres.

### STATEMENT OF THE INVENTION

In a first aspect of the invention there is provided a solar reflective fibre having a longitudinal axis, the fibre comprising:
a substantially continuous primary portion having a first refractive index; and
a plurality of secondary portions, each secondary portion having a second refractive index different from the first refractive index,
the primary and secondary portions being arranged to run substantially continuously along at least a portion of a length of the fibre,
the primary portion providing a host medium within which the secondary portions are provided,
the primary and secondary portions being arranged to constitute a dielectric mirror structure whereby a phase of a plurality of scattered beams of radiation each beam being scattered at one of a plurality of respective interfaces between primary and secondary portions interfere constructively with one another thereby to reduce an amount of solar radiation that may be transmitted through the fibre.

Preferably the dimensions of the primary and secondary portions are optimised to scatter radiation of one or more frequencies at which solar radiation has the greatest intensity over the frequency spectrum from the ultraviolet to infrared regions of the electromagnetic spectrum.

Preferably the dimensions of the primary and secondary portions are optimised to scatter radiation in the frequency range from around 450 to around 700 nm.

Alternatively the dimensions may be optimised to scatter radiation in the frequency range from around 300 nm to around 1800 nm.

Preferably the secondary portions are provided in the form of tube elements.

The tube elements may be substantially discrete elements.

Preferably the tube elements are arranged in substantially concentric rings as viewed along the longitudinal axis of the fibre.

Preferably the tube elements are provided in at least one substantially spiral-shaped arrangement as viewed along the longitudinal axis of the fibre.

Preferably the tube elements are provided in a plurality of substantially spiral-shaped arrangements as viewed along the longitudinal axis of the fibre.

Preferably the plurality of substantially spiral-shaped arrangements as viewed along the longitudinal axis of the fibre are centred about a common axis, the spiral-shaped arrangements being provided at different angular positions with respect to one another.

Preferably the common axis is coincident with a longitudinal axis of the fibre through a centroid of a cross-section of the fibre, the cross-section being a cross-section normal to said longitudinal axis.

The primary and secondary portions may be arranged such that a trajectory of a beam of light passing through a centre of the fibre along a path normal to the longitudinal axis of the fibre passes through at least a portion of the primary portion and at least one secondary portion.

Preferably a diameter of respective tube elements is a function of a distance of a tube element from the longitudinal axis of the fibre.

The diameter of a tube element may be a non-linear function of a distance of the tube element from the longitudinal axis.

Alternatively a diameter of a tube element may be a substantially linear function of a distance of the tube element from the longitudinal axis of the fibre.

The diameter of a tube element may increase as a function of distance from the longitudinal axis.

Alternatively the diameter of a tube element may decrease as a function of distance from the longitudinal axis.

Preferably the secondary portion comprises a fluid-filled void.

A fibre may be provided coupled to a fluid source, the fluid source being arranged to inject a first fluid into the fibre thereby to introduce the first fluid into the fluid-filled void.

The first fluid may have a value of refractive index substantially the same as that of the primary portion, preferably having a value within 20% of that of the primary portion, more preferably within 10% of that of the primary portion.

The fluid source may be further arranged to inject a second fluid into the fibre thereby to introduce the second fluid into the fluid-filled void.

The second fluid may have a value of refractive index different from that of the primary portion, preferably having a value differing by at least 10%, still more preferably by at least 20% from that of the primary portion.

The first fluid may have a first colour and the second fluid may have a second colour different from the first colour.

A fibre may comprise a core-shell structure, a core of the core-shell structure being provided by a tertiary portion, the shell of the core-shell structure being provided by the primary and secondary portions.

The tertiary portion may be coloured.

The fibre may comprise a transparent or translucent polymer, optionally one selected from amongst fluorinated ethylene propylene (FEP) and polypropylene.

The shell may comprise the transparent or translucent polymer.

The fibre may have a primary portion comprising a core portion and a plurality of radial spoke portions projecting in a substantially radial direction therefrom, the secondary portions being provided between respective adjacent spoke portions.

The secondary portion may be substantially tapered along a radial direction.

In a second aspect of the invention there is provided a fabric comprising a plurality of fibres according to the first aspect.

The plurality of fibres may be arranged to be switchable in colour between a first colour and a second colour different from the first colour by changing the fluid filling the secondary portions from a first fluid to a second fluid.

The first fluid may have a refractive index corresponding to that of the primary portion and the second fluid has a refractive index different from the primary portion.

The fibre may have a tertiary portion of the first colour, optionally a red colour.

The fabric may further comprise a plurality of fibres arranged to be switchable in colour between a third colour and the second colour different from the third colour by changing the fluid filling the secondary portions from the first fluid to the second fluid.

The fibre may have a tertiary portion of the third colour, optionally a green colour.

The fabric may further comprise a plurality of fibres arranged to be switchable in colour between a fourth colour and the second colour different from the fourth colour by changing the fluid filling the secondary portions from the first fluid to the second fluid.

The fibre may have a tertiary portion of the fourth colour, optionally a blue colour.

In a third aspect of the invention there is provided a garment comprising a plurality of fibres according to the first aspect.

The garment may comprise a fabric according to the second aspect.

In a fourth aspect of the invention there is provided a building comprising a plurality of fibres according to the first aspect.

In a fifth aspect of the invention there is provided a roof of a building comprising a plurality of fibres according to the first aspect.

In a sixth aspect of the invention there is provided a building comprising a fabric according to the second aspect.

In a seventh aspect of the invention there is provided a roof of a building comprising a fabric according to the second aspect.

In an eighth aspect of the invention there is provided a solar concentrator comprising a reflector comprising a plurality of fibres according to the first aspect arranged to focus solar radiation onto a solar cell.

The solar concentrator may be arranged to change a shape of the reflector as a function of time thereby to reduce an amount of decrease in intensity of reflected solar radiation due to movement of the sun during the course of a day or portion thereof.

In a ninth aspect of the invention there is provided an aircraft comprising a plurality of fibres according to the first aspect arranged to reflect solar radiation thereby to reduce an amount by which a temperature of the aircraft rises due to solar radiation.

The aircraft may be a lighter-than-air aircraft.

The aircraft may be one selected from amongst a blimp and an airship.

In a tenth aspect of the invention there is provided a composite material comprising a plurality of fibres according to the first aspect.

Preferably the material is a fibre reinforced composite material.

The reinforcing fibres may be fibres according to the first aspect.

In an eleventh aspect of the invention there is provided apparatus comprising a plurality of fibres according to the first aspect arranged to change an opacity of the fibre by changing a refractive index of a fluid introduced into the secondary portions of the fibre.

Preferably the apparatus comprises at least one fibre having a tertiary portion of a first colour and at least one fibre having a tertiary portions of a second colour different from the first colour.

The apparatus may be arranged to change an opacity of the shell portion of the fibre by changing a refractive index of a fluid introduced into the secondary portions of the fibre.

The apparatus may be arranged to vary the opacity of the fibre between different respective values at a sufficiently high rate to provide a viewer with an impression that the opacity of the fibre has a value between that of the fibre when the secondary portions are filled with the first fluid and that when the secondary portions are filled with the second fluid.

In a twelfth aspect of the invention there is provided display apparatus comprising a 2D array of fibres according to the first aspect, the apparatus comprising a fluid source arranged to sequentially inject a required amount of one of a plurality of fluids of different respective refractive indices into each fibre whereby a 2D variation in reflectivity of portions of a fibre and portions of respective different fibres may be established within the array.

Preferably the display apparatus is arranged to receive data corresponding to pixels of an image, the apparatus being arranged to provide a sequence of pulses of respective different fluids to respective different fibres thereby to generate a 2D variation in reflectivity of the array corresponding to contrast in the image defined by the received data.

Preferably at least one of the fluids is a liquid fluid and at least one of the fluids is a gaseous fluid.

A plurality of the fluids may be liquid fluids of different respective colours, the apparatus being arranged to allow an image to be created having a 2D variation in colour.

The plurality of fluids may comprise a red fluid, a green fluid and a blue fluid.

In a further aspect of the invention there is provided apparatus comprising:
a solar reflective fibre having a plurality of voids provided along at least a portion of a length thereof; and p1 a fluid source coupled to the plurality of voids,
the apparatus being operable to fill the plurality of voids with fluid, the apparatus being further operable to remove the fluid from the plurality of voids wherein the voids become filled with a gas,
wherein with the plurality of voids filled with gas the fibre is arranged to provide a dielectric mirror structure wherein a phase of a plurality of scattered beams of radiation, each beam being scattered at one of a plurality of respective interfaces between the voids and a portion of the fibre defining the voids, interfere constructively with one another thereby to reduce an amount of radiation transmitted through the fibre.

Each void may comprise a tube element.

### BRIEF DESCRIPTION OF THE DRAWINGS

Embodiments of the invention will now be described with reference to the accompanying figures in which:

FIG. 1 is a cross-sectional view of a fibre according to an embodiment of the invention having concentric rings of tube members running along a length of the fibre;

FIG. 2 is a cross-sectional view of a fibre according to an embodiment of the invention having multiple spiral-shaped arrangements of tube members running along a length of the fibre;

FIG. 3 is a cross-sectional view of a fibre according to an embodiment of the invention having radially tapered spoke elements angularly spaced about a hub portion and running along a length of the fibre;

FIG. 4 is a cross-sectional view of a fibre according to an embodiment of the invention in which a fibre has a core/shell structure, the shell portion of the structure having tube members therein running along a length of the fibre;

FIG. 5 is a plan view of a fabric having a plurality of fibres therein formed according to an embodiment of the invention woven with a plurality of prior art fibres; and

FIG. 6 is a plan view a fabric having a plurality of fibres formed according to an embodiment of the invention and having a core/shell structure, respective fibres having core portions arranged to reflect red, green or blue light when a shell portion of the fibre is in a substantially non-reflective state.

### DETAILED DESCRIPTION

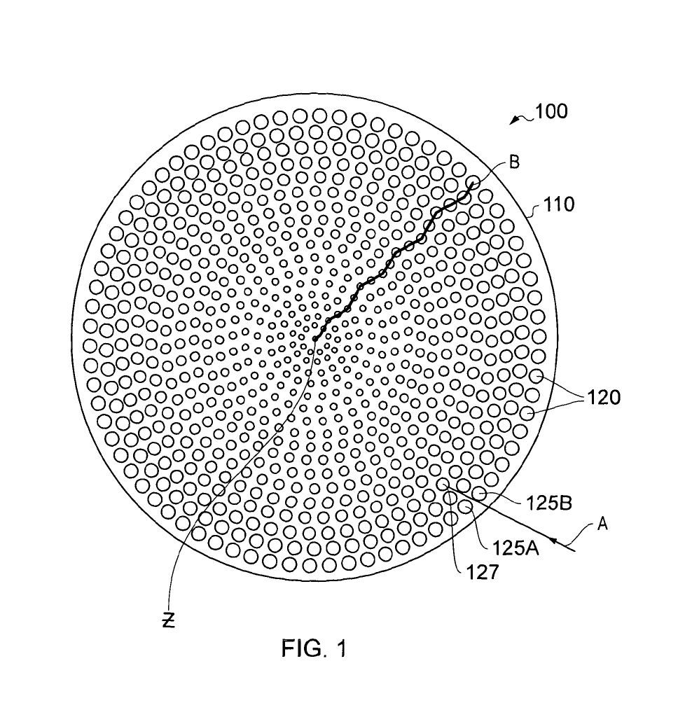

FIG. 1 is a cross-sectional view of a fibre 100 according to an embodiment of the present invention. The fibre 100 has a primary portion 110 in the form of a substantially cylindrical member. The primary portion 110 has a plurality of secondary portions 120 in the form of hollow tube elements 120 running therethrough substantially parallel to a longitudinal axis z of the fibre 100. The tube elements 120 are arranged in concentric rings, a diameter of the tube elements 120 of a given ring being a function of a radius of that ring.

In the embodiment of FIG. 1 tube elements 120 of respective rings are arranged to be circumferentially staggered with respect to one another along a radial direction. Thus, a beam of light A entering the fibre along a given path and penetrating the fibre beyond a first (outermost) concentric ring 125 of tube elements 120 between elements 125A, 125B of the outermost ring will encounter at least one tube element 127 as the beam A travels through the fibre 100.

That concentric rings of tube elements are circumferentially staggered with respect to one another is also illustrated by line B of FIG. 1 which connects centres of nearest neighbour tube elements of respective immediately adjacent concentric rings. It is to be noted that the line is not a straight line, as would be the case if respective immediately adjacent concentric rings were circumferentially aligned.

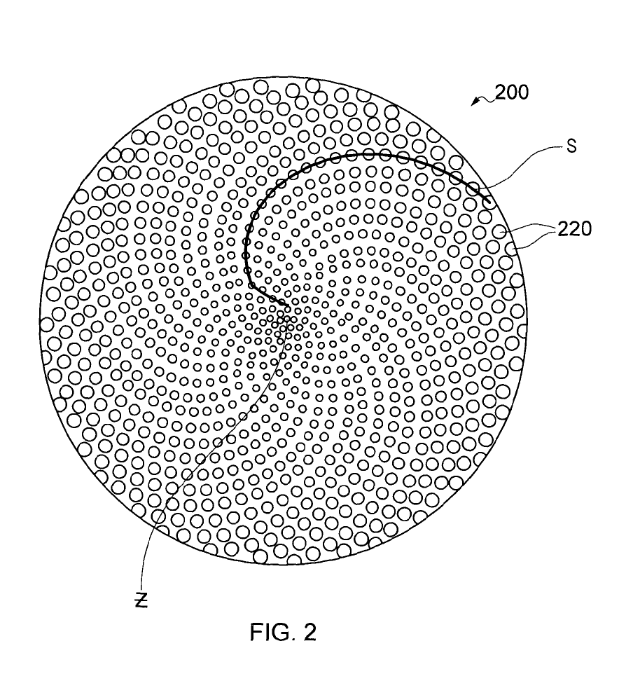

FIG. 2 is a cross-sectional view of a fibre 200 according to a further embodiment of the invention having multiple spiral-shaped arrangements of tube elements 220. Respective spiral arrangements are angularly displaced with respect to one another about a longitudinal or cylinder axis z of the fibre 200. Line S connects centres of tube elements 220 corresponding to one particular spiral arrangement. It is to be noted that close to the cylinder axis z overlap of respective arrangements occurs. In the embodiment shown, in the region where such overlap takes place a location is chosen for a tube element 220 that is substantially equidistant from adjacent tube elements 220. Other arrangements are also useful.

In the embodiment of FIG. 2 the tube elements 220 have an Archimedean spiral arrangement, wherein polar coordinates (R, θ) of tube elements 220 are given by:

R=0.26*N^{0.65}

θ=N*137.5°

where N is an index between 1 and 800.

The tube elements 120, 220 of the embodiments of FIG. 1 and FIG. 2 have a diameter and placement within the respective fibre 100, 200 arranged to enhance a reflectivity of the fibre 100, 200 to solar radiation. In the embodiments of FIG. 1 and FIG. 2 tube elements 120, 220 at or close to a centre of the fibre 100, 200 have a diameter of 208 nm. Other values are also useful. Tube elements 120, 220 at the peripheral edge of the fibre 100, 200 have a diameter of 554 nm. Other values are also useful. The diameter of the tube elements 120, 220 varies linearly as a function of distance of a centre of a tube element 120, 220 from a cylinder axis z of the fibre 120, 220.

In the embodiments shown the diameter of the fibre 100, 200 is around 20 microns (um). Other diameters are also useful.

It is to be understood that in the embodiment of FIG. 1 a diameter of successive rings may increase in a non-linear manner due to the increase in diameter of tube elements 120 of each successive ring.

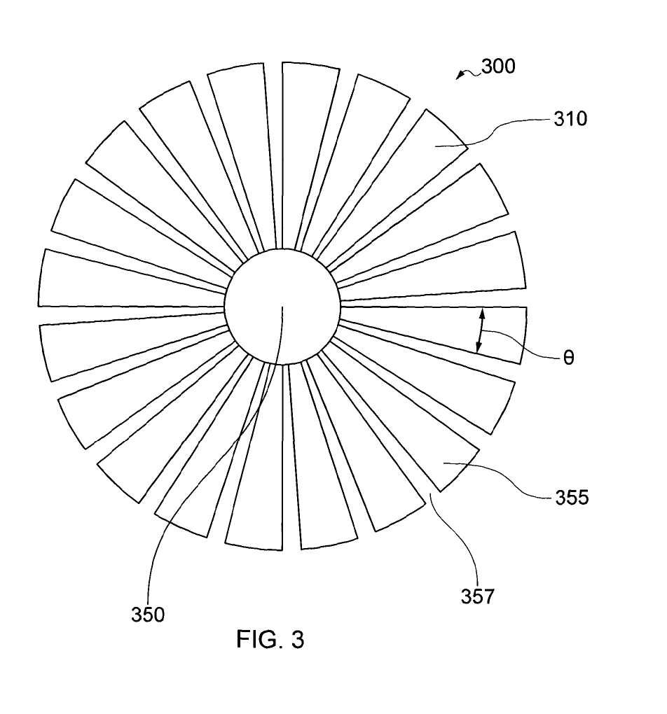

FIG. 3 shows a fibre 300 according to an embodiment of the invention having a segmented pie structure.

The fibre has a core portion 350 in the form of a cylindrical portion having a plurality of substantially wedge-shaped radial formations 355 protruding therefrom in a radial direction. The radial formations 355 are angularly spaced about the core portion 350 in a substantially uniform manner. Voids 357 are present between the radial formations 355. The core portion 350 and radial formations 355 together provide a primary portion 310.

In some embodiments having the segmented pie structure, low refractive index segments (gas-filled segments in the embodiment of FIG. 3) have a lower angular dimension than higher refractive index segments.

In the example of FIG. 3 the fibre 300 has a diameter of 20 um and each radial formation 355 has an internal wedge angle θ of around 14° and an angular spacing between radial formations 355 of around 4°.

The fibres 100, 200, 300 shown in the figures are manufactured by a bi-component fibre process in which a first polymer (providing the primary portion 110, 210, 310) is provided with a second polymer therein.

In the embodiments of FIG. 1 and FIG. 2 the second polymer is provided in the first polymer at locations corresponding to those of the tube elements 120, 220 of the final fibre 100, 200 whilst in the embodiment of FIG. 3 the second polymer is provided in the first polymer at locations corresponding to those of voids 357 in the final fibre 300.

In some embodiments the second polymer is a water soluble polymer. Immersion of a fibre in water thereby results in removal of the second polymer from the first polymer.

In some embodiments such as those of FIG. 1 and FIG. 2 a process or extraction is employed to remove the water-soluble polymer from within the tube members.

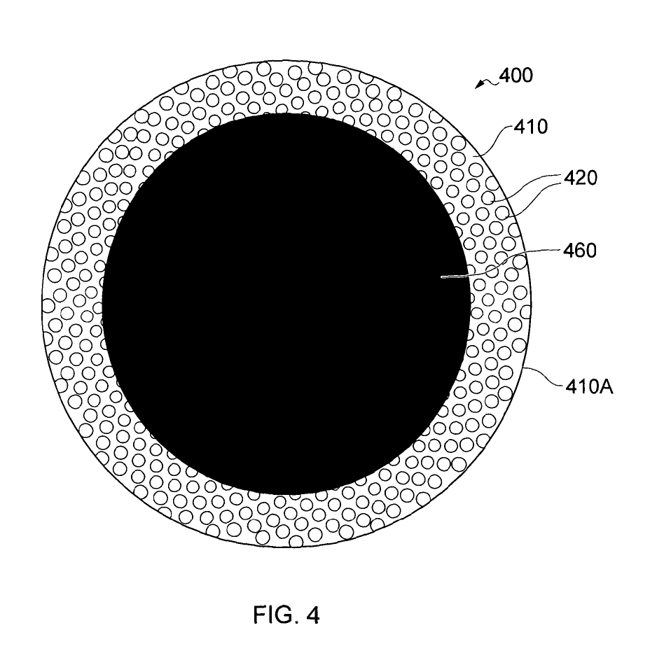

FIG. 4 shows an embodiment in which a fibre 400 is provided having a core/shell structure. The fibre 400 has a core portion 460 and a shell portion 410A.

In the embodiment of FIG. 4 the core portion 460 is a cylindrical member formed from a plastics material. The shell portion 410A has a primary portion 410 containing a plurality of tube elements 420. In the embodiment of FIG. 4 the positions of the tube elements 420 corresponds to those of the embodiment of FIG. 2 described above.

It is to be understood that fibres according to embodiments of the present invention may be woven with other fibres according to embodiments of the invention or with conventional, known fibres.

For example, orthogonal arrays of fibres according to embodiments of the invention may be woven. Alternatively fibres according to embodiments of the invention may be woven together with known fibres, for example in a parallel arrangement with known fibres and/or an orthogonal arrangement with known fibres.

In the case that orthogonal arrays of fibres according to the present invention are woven, the presence of orthogonal fibres is advantageous in some embodiments. This is because if a ray of light is incident on the fibre along a direction that is not perpendicular to the fibre a likelihood of scattering of the light may be increased in the case of an orthogonal array. The reason for this may be understood from trigonometrical considerations.

In the case of a simple planar dielectric mirror, the mirror is typically formed to have alternating layers of low and high refractive index material, each layer being around 0.25λ in thickness. Strongest reflection of radiation is therefore achieved when light is incident on the layers normal to a plane of the layers.

It is to be understood that a disadvantage of such a construction is that it is optimised for light incident on the layers normal to a plane of the layers such that the light has a path length of 0.25λ through each layer.

If the light is incident on the mirror at a shallower angle, the path length of the light will be greater than 0.25λ. The performance of the mirror will therefore be reduced.

In a similar manner, a reflectivity of a fiber according to embodiments of the invention is optimised for light incident on the fibre perpendicular to the fiber although it is to be understood that fibres may be optimised for light incident upon them at a different angle or a plurality of angles.

It is to be understood that a perpendicular slice though a fiber of circular cross-section will be substantially circular. A slice though a fiber at any other angle will produce an ellipse.

Hollow tube elements running parallel to a longitundinal axis of the fibre and having a circular cross-section will also present an elliptical section when the fibre is cut at an angle other than an angle normal to the fibre axis. Thus a path length of light through regions of a fibre of different respective refractive indices will depend on an angle at which the light is incident on the fibre in a similar manner to the planar dielectric mirror described above.

It is to be understood that an extent to which radiation will be scattered by the fibre will be reduced when the radiation is incident on the fibre along a direction that is not perpendicular to the fibre axis.

However, if fibres are provided in an orthogonal array, for example in the form of a weave of fibres oriented at substantially 90° to one another, an extent to which a ray of light can deviate from an angle normal to a fibre axis is limited to around 45°. Thus, an extent to which reflectivity of the weave can be degraded may be reduced in some embodiments when an orthogonal array is used.

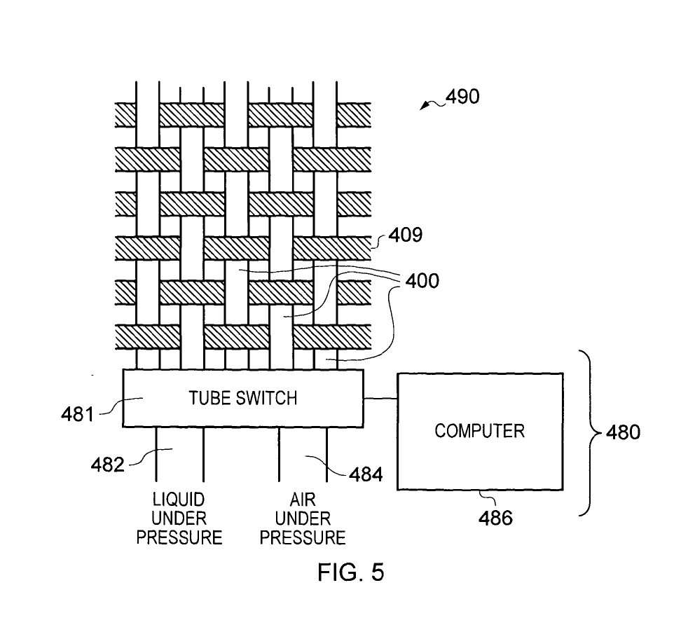

FIG. 5 shows a fabric 490 woven from fibres 400 according to the embodiment of FIG. 4 and conventional known fibres 409.

The fibres 400 are arranged to run parallel to one another, the conventional fibres 409 being arranged to run parallel to one another but orthogonal to the fibres 400. The fibres 400 are coupled at one end to fluid injection apparatus 480.

The fluid injection apparatus 480 is arranged to inject one of a pair of fluids (a first fluid and a second fluid) into the tube elements 420 of the fibres 400. In the embodiment shown a first fluid is supplied to a switch module 481 via a first conduit 482 whilst a second fluid is supplied to the switch module 481 via a second conduit 484.

In the embodiment shown the first fluid corresponds to liquid whilst the second fluid corresponds to a gas, optionally air.

A computing device 486 is arranged to control the switch module 481 whereby either the first or second fluid is injected into the tube elements 420 of one or more of the fibres 400.

In the embodiment shown the liquid has a refractive index similar to that of the transparent or translucent medium from which the primary portion 410 of the fibre 400 is formed. Thus, when liquid is injected, the primary portion appears to be transparent or translucent.

However, the medium from which the primary portion 410 is formed has a refractive index such that when the liquid is replaced by a gas, the primary portion becomes highly reflective.

In the embodiment of FIG. 4 the fibre 400 has a core portion 460 that becomes visible to an observer when the above described liquid is present in the tube elements 420 of the shell portion 410A. When the gas is present in the tube elements 420, the core portion 460 is obscured due to reflection of light by the shell portion 410A.

It is to be understood that fibres not having a the core portion 460 are also useful. Thus, in some embodiments fibres 100, 200 according to the embodiments of FIG. 1 or FIG. 2 may be used. The fibres 100, 200 may be switched between a condition in which the fibre is translucent or transparent (depending on the material from which the primary portion is formed) and a condition in which a reflectivity of the fibre to solar radiation is increased. In the condition in which reflectivity of the fibre is increased, light is scattered at interfaces between tube elements and the primary portion of each fibre in a constructive manner thereby providing a dielectric mirror or dielectric mirror-like reflector structure.

It is to be understood that the core portion 460 may be made to be of a particular colour. Thus, by switching a fibre between a condition in which the tube elements 420 are liquid filled and a condition in which the tube elements 420 are gas filled, as described above, the colour can be visible or invisible to a viewer. Other arrangements are also useful.

It is to be understood that fibres having core portions 460 having different respective colours may be provided in a fabric thereby to allow a range of visual effects to be created.

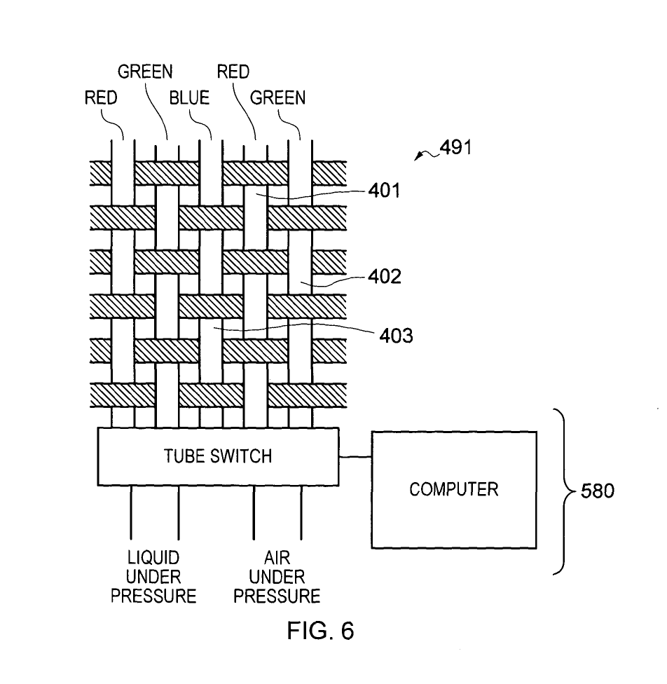

FIG. 6 shows an embodiment in which a fabric 491 has been woven having repeated sequences of adjacent fibres 401, 402, 403 thereacross. Respective fibres 401, 402, 403 have core portions 460 having a red, green and blue colour respectively. It is to be understood that a range of colour effects may be obtained by switching the shell portions 410A of the fibres between light reflecting and light transmitting states as described above.

Furthermore, whilst some fibres reflect a broad spectrum of colours in order to increase an amount of energy reflected by the fibres, some fibres are arranged to reflect only a narrower range of frequencies. For example, respective fibres can be provided that reflect light predominantly at the red, green and blue regions of the spectrum. A fabric constructed from these fibres might be arranged to reflect any required colour combination. The fabric may optionally be backed with a black cloth or other substantially black material.

In some embodiments a liquid or a gas injected into the fibre is coloured. For example the liquid or gas may be a red, green or blue gas or liquid.

In some embodiments, an extent to which a fibre appears to a user to be reflective of light may be varied by rapidly switching between light transmitting and light reflecting states thereby allowing a contrast level of an appearance of a core portion 460 of a fibre 400 to be varied. Such a switching technique can also be applied to fibres 100, 200 not having a core portion 460.

Embodiments of the invention may be used to vary an amount of heat energy that is allowed to penetrate the fabric. It is to be understood that fabrics 490, 491 according to embodiments of the invention are useful in a range of applications including clothing, building structures, building furnishings, protective covers and a range of other applications.

Some embodiments of the invention provide a structure in which an array of fibres are provided, the array being arranged to display a 2D image.

Taking the structure of FIG. 5 as an example, the switch module 481 may be arranged to successively inject pulses of liquid or gas into tube elements 420 of a given fibre, such that a variation of refractive index may be established along a length of the fibre.

By performing a similar process with each fibre, a 2D image may be generated in which contrast is provided by variations in reflectivity of respective fibres along the length of each fibre.

It is to be understood that in some embodiments a time required to change a 2D image will depend upon a time required to pump a new arrangement of liquid and gas regions through a fibre. In some embodiments an illusion of movement of features of an image such as text may be created.

In some embodiments an image is provided arranged to allow an area of a subject to be selectively exposed to light incident on the array of fibres, the array being provided between the subject and the light source.

It is to be understood that liquids of different respective colours might be injected into the fibres, to allow variations in colour of an image to be generated. For example, in some embodiments apparatus is provided allowing red, green and blue liquids to be successively injected into a given fibre.

It is to be understood that in some embodiments fibres according to embodiments of the invention are formed into a fabric optimised to reflect the most solar radiation for the purpose of cooling by having a plurality of overlapping fibres at right angles to one another, the fibres containing tubular elements whose diameter and spacing varies as a function of position across the fibre cross-section as described above.

The fibres may be arranged to reflect the frequencies of solar radiation containing the majority of the energy, for example the frequencies from the infra-red to the ultraviolet regions of the electromagnetic spectrum that contain the majority of the energy in that range.

It is to be understood that the size and locations (or placement) of tube elements within a fibre may be determined according to a range of optimisation techniques.

In one embodiment, optimisation of the structure of a fibre in respect of the position and size of the tube elements within the fibre is performed by simulating interaction of light with the fibre. The interaction may be simulated using a finite element solution to Maxwell's equations.

In one embodiment interaction of a plurality of rays with the fibre at different angles (e.g. different respective azimuths and elevations) is studied in order to simulate rays approaching a fibre from all possible directions.

In the case of optimisation of a fibre having tube elements arranged in an Archimedean spiral as viewed in cross-section, one or more of a number of different variables may be optimised, including: (1) tightness of the spiral (i.e. an angular rate of increase of diameter of the spiral, or diameter as a function of angle of turn from a radially outer position to a radially inner position); (2) spacing between tube elements, (3) the diameter of the smallest tube element and (4) the diameter of the largest tube element.

The arrangement of fibres in this and other embodiments may be arranged to rotate or twist as a function of distance along a fibre, for example in a helical manner.

For a given choice of variable values, a simulation of light interaction with a fibre may be performed for a set of optical frequencies between 300 nm and 1800 nm. The average value of reflectivity is recorded. Other frequencies and frequency ranges are also useful.

Each variable is quantised. Quantisation is performed by determining the largest step in value that has less than a 1% change in reflectivity. The maximum and minimum values of each variable are chosen based on geometrical constraints and general knowledge of light scattering theory. Given sufficient computing resource, an exhaustive search of the 4-variable space would yield an optimal result.

With the current performance of computers an exhaustive search might take a prohibitive length of time. The computing power required by the search may be reduced by holding a number of variables constant whilst the rest of the variables are searched, optionally exhaustively searched. This may be followed by changing the variable(s) that are held constant.

Such a procedure of optimisation, although relatively unsophisticated, could be replaced by general purpose optimising algorithms. This may reduce the search space at a risk of finding a local minimum or minima.

Throughout the description and claims of this specification, the words “comprise” and “contain” and variations of the words, for example “comprising” and “comprises”, means “including but not limited to”, and is not intended to (and does not) exclude other moieties, additives, components, integers or steps.

Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith.

1. A solar reflective fibre having a longitudinal axis, the fibre comprising:
a substantially continuous primary portion having a first refractive index; and
a plurality of secondary portions, each secondary portion having a second refractive index different from the first refractive index,
the primary and secondary portions being arranged to run substantially continuously along at least a portion of a length of the fibre,
the primary portion providing a host medium within which the secondary portions are provided,
the primary and secondary portions being arranged to constitute a dielectric mirror structure optimised such that a phase of a plurality of scattered beams of radiation each beam being scattered at one of a plurality of respective interfaces between primary and secondary portions interfere constructively with one another thereby to reduce an amount of solar radiation transmitted through the fibre.

2. A fibre as claimed in claim 1 wherein the secondary portions are provided in the form of tube elements.

3. A fibre as claimed in claim 1 wherein the tube elements are substantially discrete elements.

4. A fibre as claimed in claim 1 wherein the tube elements are arranged in substantially concentric rings as viewed along the longitudinal axis of the fibre.

5. A fibre as claimed in claim 1 wherein the tube elements are provided in at least one substantially spiral-shaped arrangement as viewed along the longitudinal axis of the fibre.

6. A fibre as claimed in claim 5 wherein the tube elements are provided in a plurality of substantially spiral-shaped arrangements as viewed along the longitudinal axis of the fibre.

7. A fibre as claimed in claim 6 wherein the plurality of substantially spiral-shaped arrangements as viewed along the longitudinal axis of the fibre are centred about a
common axis, the spiral-shaped arrangements being provided at different angular positions with respect to one another.

8. A fibre as claimed in claim 7 wherein the common axis is coincident with a longitudinal axis of the fibre through a centroid of a cross-section of the fibre, the cross-section being a cross-section normal to said longitudinal axis.

9. A fibre as claimed in claim 1 wherein the primary and secondary portions are arranged such that a trajectory of a beam of light passing through a centre of the fibre along a path normal to the longitudinal axis of the fibre passes through at least a portion of the primary portion and at least one secondary portion.

10. A fibre as claimed in claim 2 wherein a diameter of respective tube elements is a function of a distance of a tube element from the longitudinal axis of the fibre.

11. A fibre as claimed in claim 10 wherein the diameter of a tube element is a nonlinear function of a distance of the tube element from the longitudinal axis.

12. A fibre as claimed in claim 10 wherein a diameter of a tube element is a substantially linear function of a distance of the tube element from the longitudinal axis of the fibre.

13. A fibre as claimed in claim 10 wherein the diameter of a tube element increases as a function of distance from the longitudinal axis.

14. A fibre as claimed in claim 10 wherein the diameter of a tube element decreases as a function of distance from the longitudinal axis.

15-20. (canceled)

21. A fibre as claimed in claim 1 comprising a core-shell structure, a core of the core-shell structure being provided by a tertiary portion, the shell of the core-shell structure being provided by the primary and secondary portions.

22. A fibre as claimed in claim 21 wherein the tertiary portion is coloured.

23. A fibre as claimed in claim 1 wherein the fibre comprises a transparent or translucent polymer, optionally one selected from amongst fluorinated ethylene propylene (FEP) and polypropylene.

24. A fibre as claimed in claim 23 wherein the shell comprises the transparent or translucent polymer.

25. A fibre as claimed in claim 1 having a primary portion comprising a core portion and a plurality of radial spoke portions projecting in a substantially radial direction therefrom, the secondary portions being provided between respective adjacent spoke portions.

26. A fibre as claimed in claim 25 wherein the secondary portions are substantially tapered along a radial direction.

27. A fibre as claimed in claim 1 wherein the primary and secondary portions are arranged such that the phase of a plurality of scattered beams of radiation each beam being scattered at one of a plurality of respective interfaces between primary and secondary portions interfere constructively with one another thereby to reduce an amount of solar radiation transmitted through the fibre in the spectral range from around 300 nm to around 1800 nm.

28. A fabric comprising a plurality of fibres as claimed in claim 1.

29-35. (canceled)

36. A garment comprising a plurality of fibres as claimed in claim 1.

37. (canceled)

38. A building comprising a plurality of fibres as claimed in claim 1.

39-41. (canceled)

42. A solar concentrator comprising a reflector comprising a plurality of fibres as claimed in claim 1arranged to focus solar radiation onto a solar cell.

43-66. (canceled)
